(19) United States
(12) Patent Application Publication
(10) Pub. No.: US 2009/0026470 A1
(43) Pub. Date: Jan. 29, 2009

(54) SUPER THIN SIDE-VIEW LIGHT-EMITTING DIODE (LED) PACKAGE AND FABRICATION METHOD THEREOF

(75) Inventors: Kou-Rueh Lai, Hsinchu City (TW); Kung-Chi Ho, Hsinchu County (TW); Hu-Chen Tsai, Hsinchu County (TW); Po-Kai Huang, Kaohsiung County (TW); Ming-Sing Lai, Kaohsiung County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NOVALITE OPTRONICS CORP., Hsinchu City (TW)

(21) Appl. No.: 11/781,279

(22) Filed: Jul. 23, 2007

(51) Int. Cl. H01L 33/00

(52) U.S. Cl. 257/98; 438/27; 257/E33.061

(57) ABSTRACT

A fabrication method of a side-view LED package is provided. A chip carrier is provided. An opaque housing is bonded with the chip carrier. An LED chip electrically connects the chip carrier by performing a chip-bonding process and the opaque housing has a cavity for accommodating the LED chip. A transparent encapsulant is disposed in the cavity wherein the transparent encapsulant has a side-view light output surface uncovered by the opaque housing and light emitted from the LED chip is output via the side-view light output surface. A portion of the opaque housing and a portion of the transparent encapsulant are removed for reducing an overall thickness of the opaque housing such that a top surface of the transparent encapsulant is uncovered by the opaque housing beside the side-view light output surface. An opaque protective layer is formed on the top surface of the transparent encapsulant and the opaque housing.

### BACKGROUND OF THE INVENTION

1. Field of the Invention

The present invention relates to a light-emitting diode (LED) package and a fabrication method thereof. More particularly, the present invention relates to a side-view light-emitting diode (LED) package with ultra-thin thickness and a fabrication method thereof.

2. Description of Related Art

Since the light-emitting diode (LED) has such advantages as long service life, small volume, high shock resistance, low heat output, and low power consumption, it has been widely utilized in indicators or light sources for household appliances and various instruments. In recent years, the LED has been developed towards multicolor and high brightness; therefore, its application scope has been expanded to large outdoor display boards, traffic signal lights, and the like. In the future, it may even become the main illumination light source with both power-saving and environment-protecting functions.

As a result of the development of small displays devices, the thickness of the illumination light source must become thinner and thinner. For example, a side-view LED package of about 0.6 millimeter in thickness had been produced. FIG. 1A shows a conventional side-view LED package of 0.6 millimeter in thickness. Referring to the FIG. 1, the side-view LED package 100 includes a carrier 110, an opaque housing 120, an LED chip 130, a plurality of bonding wires 140, and a transparent encapsulant 150. The opaque housing 120 encapsulates a part of the carrier 110, so as to define a chip-accommodating space S over the carrier 110. The LED chip 130 is disposed on the carrier 110 and located in the chip-accommodating space S. The LED chip 130 is electrically connected the carrier 110 via the bonding wires 140. The transparent encapsulant 150 is disposed in the chip-accommodating space S and encapsulates the LED chip 130 and bonding wires 140. The overall thickness D of the side-view LED package 100 is about 0.6 millimeter. As shown in FIG. 1A, the overall thickness D of the side-view LED package 100 is related to the volume of the chip-accommodating space S. In other words, the smaller the chip-accommodating space S is, the thinner the side-view LED package 100 will be.

FIG. 1B shows a mold for fabricating the conventional side-view LED package. Referring to FIG. 1A and FIG. 1B, when the opaque housing 120 is fabricated, a first mold M1 having a cavity C and a second mold M2 having a slim protrusion P is used. If manufacturer want to further reduce the overall thickness D of the side-view LED package 100, it is necessary to reduce the volume of the chip-accommodating space S. During the fabrication of the conventional side-view LED package 100 with an overall thickness less than 0.6 millimeter, the slim protrusion P with a thickness smaller less 0.3 millimeter is used. However, the slim protrusion P with the thickness smaller less 0.3 millimeter is difficult to manufacture, in addition, the slim protrusion P with a thickness smaller less 0.6 millimeter deforms easily when performing an injection molding process. Hence, the thickness of the side-view LED package 100 having thickness less than 0.6 millimeter is not fabricated easily. In other words, the yield rate of fabricating the side-view LED package 100 having thickness less than 0.6 millimeter is quite low.

### SUMMARY OF THE INVENTION

Accordingly, the present invention is directed to a fabrication method of a side-view LED package so as to enhance yield rate.

The present invention is directed to a side-view LED package with an ultra-thin thickness.

As embodied and broadly described herein, the present invention provides a fabrication method of a side-view LED package. First, a chip carrier of lead frame substrate plus an opaque housing is provided. The opaque housing has a cavity for accommodating the light-emitting diode chip. Next, a chip-bonding process is performed for electrically connecting a light-emitting diode chip with the chip carrier. Then, a transparent encapsulant mixed with Phosphor, for example, is disposed in the cavity, wherein the transparent encapsulant has a side-view light output surface uncovered by the opaque housing and light emitted from the light-emitting diode chip is output via the side-view light output surface. Thereafter, a portion of the opaque housing and a portion of the transparent encapsulant are removed for reducing an overall thickness of the opaque housing such that a top surface of the transparent encapsulant is uncovered by the opaque housing beside the side-view light output surface. Then, an opaque protective layer is formed on the top surface of the transparent encapsulant and the opaque housing.

In one embodiment of the present invention, the above-mentioned chip carrier comprises a lead frame or a circuit board.

In one embodiment of the present invention, the above-mentioned chip-bonding process comprises a wire-bonding process or a flip-chip bonding process.

In one embodiment of the present invention, the method for forming the above-mentioned opaque housing comprises injection molding.

In one embodiment of the present invention, the method for forming the above-mentioned transparent encapsulant comprises dispensing or mold injection.

In one embodiment of the present invention, the method for forming the above-mentioned transparent encapsulant comprises providing a transparent compound having Phosphor material mixed therein and filling the transparent compound into the cavity.

In one embodiment of the present invention, the overall thickness of the above-mentioned opaque housing and the above-mentioned transparent encapsulant is about 0.5 millimeter to 0.8 millimeter before the portion of the opaque housing and the portion of the transparent encapsulant is removed.

In one embodiment of the present invention, the overall thickness of the above-mentioned opaque housing and the above-mentioned transparent encapsulant is about 0.35 millimeter to 0.45 millimeter after the portion of the opaque housing and the portion of the transparent encapsulant is removed.

In one embodiment of the present invention, the above-mentioned method of removing the portion of the opaque housing and the portion of the transparent encapsulant comprises cutting or grinding.

In one embodiment of the present invention, the above-mentioned method of forming the opaque protective layer comprises coating, screen printing, or sputtering. The material of the above-mentioned opaque protective layer, for example, comprises a polymer and a plurality of particles mixed therein. The polymer, for example, comprises Oligo-polymer, Silicon, Epoxy or Acrylic. The material of the particles, for example, comprises metal, Titanium Dioxide, Aluminum Oxide or Phosphor.

In one embodiment of the present invention, the thickness of the above-mentioned opaque protective layer is about 0.01 millimeter to 0.15 millimeter.

As embodied and broadly described herein, the present invention further provides a side-view LED package including a chip carrier, a light-emitting diode chip, an encapsulant and a protective opaque layer. The opaque housing is bonded with the chip carrier, wherein the opaque housing has a cavity for accommodating the light-emitting diode chip. The light-emitting diode chip is electrically connected with the chip carrier. The encapsulant comprises a transparent encapsulant. The transparent encapsulant is disposed in the cavity, wherein the transparent encapsulant has a side-view light output surface uncovered by the opaque housing, the transparent encapsulant has a top surface beside the side-view light output surface uncovered by the opaque housing, and light emitted from the light-emitting diode chip is output via the side-view light output surface. Additionally, an opaque protective layer is disposed on the removed surface of the transparent encapsulant and the opaque housing.

In one embodiment of the present invention, the above-mentioned chip carrier comprises a lead frame or a circuit board.

In one embodiment of the present invention, the overall thickness of the above-mentioned encapsulant and the above-mentioned opaque protective layer is about 0.5 millimeter to 0.8 millimeter.

In one embodiment of the present invention, the material of the above-mentioned opaque protective layer comprises a polymer and a plurality of particles mixed therein.

In one embodiment of the present invention, the above-mentioned polymer comprises Oligo-Polymer.

In one embodiment of the present invention, the material of the above-mentioned particles comprise metal, Titanium Dioxide, Aluminum Oxide or Phosphor.

In one embodiment of the present invention, the above-mentioned thickness of the above-mentioned opaque protective layer is about 0.01 millimeter to 0.15 millimeter.

In one embodiment of the present invention, the material of the above-mentioned transparent encapsulant comprises Silicon, Epoxy or Acrylic.

In one embodiment of the present invention, the material of the above-mentioned transparent encapsulant further comprises a Phosphor material.

In the present invention, since a portion of the opaque housing and a portion of the transparent encapsulant is removed for reducing the overall thickness of the side-view LED package, the mold used for fabricating the opaque housing is not necessary to be modified and the cost is decreased significantly. Additionally, the yield rate of the fabrication method of the side-view LED package is enhanced.

In order to the make the aforementioned and other objects, features, and advantages of the present invention comprehensible, preferred embodiments accompanied with figures are described in detail below.

### BRIEF DESCRIPTION OF THE DRAWINGS

FIG. 1A shows a conventional side-view LED package of 0.6 millimeter in thickness.

FIG. 1B shows a mold for fabricating the conventional side-view LED package.

FIG. 2A to FIG. 2F show the schematic views of the fabrication method of the side-view LED package according to an embodiment of the present invention.

FIG. 3A to FIG. 3D show the cross-sectional views of the fabrication method of the side-view LED package along the dash line A-A′ respectively in FIG. 2A to FIG. 2D.

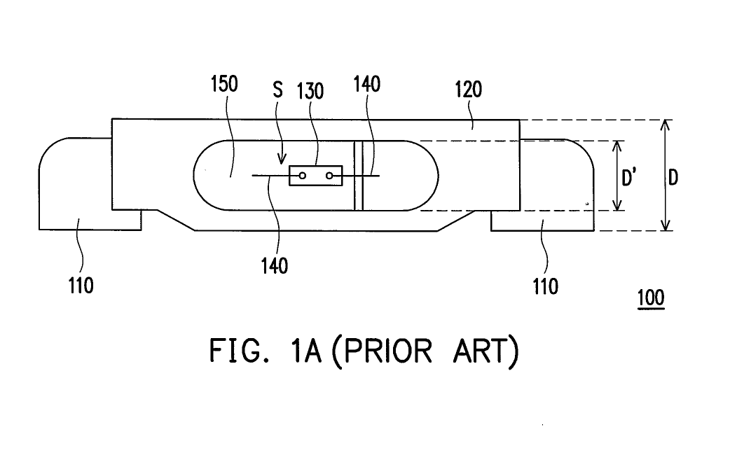

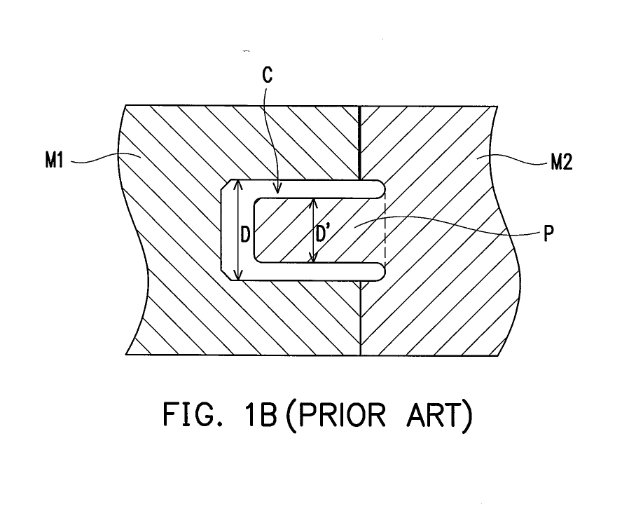

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

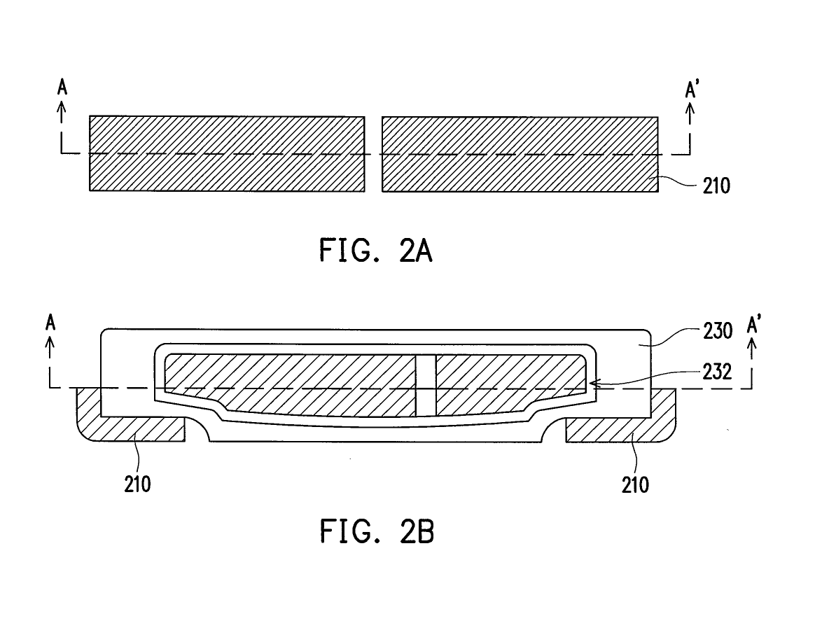

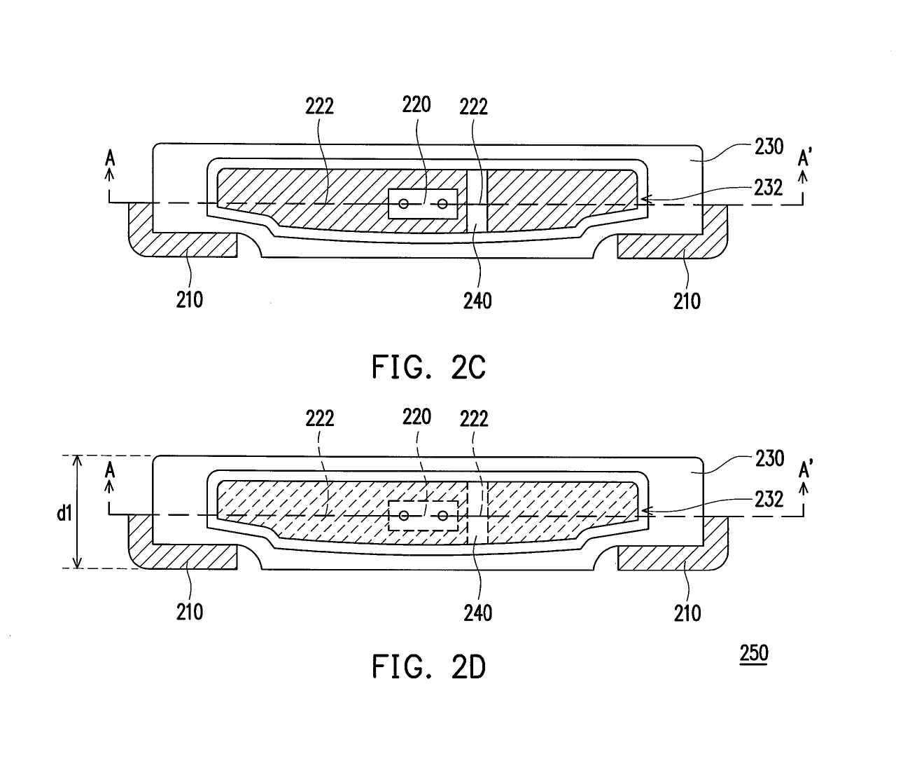

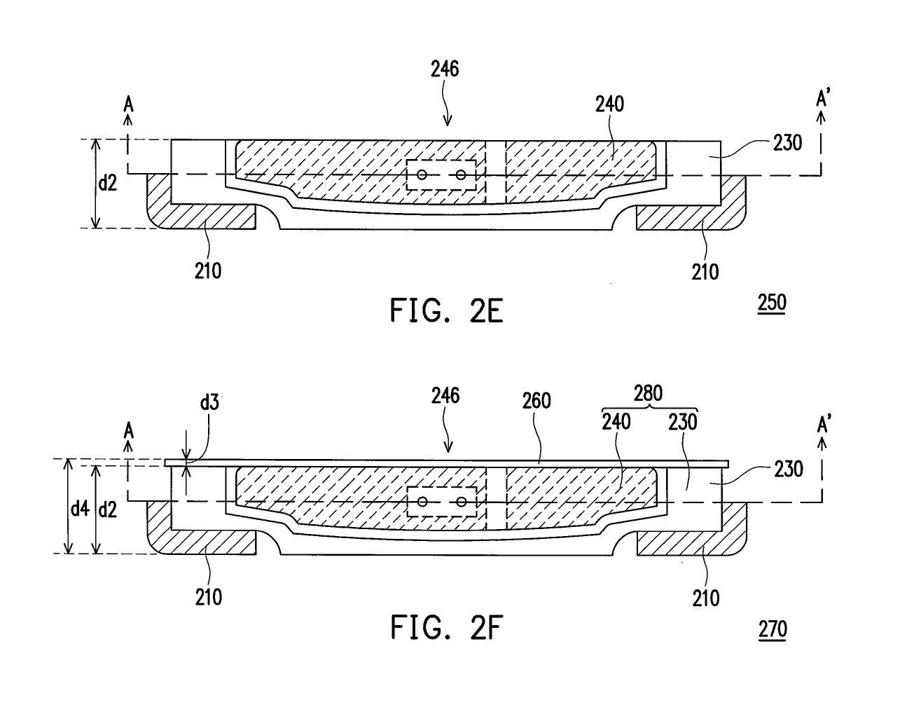

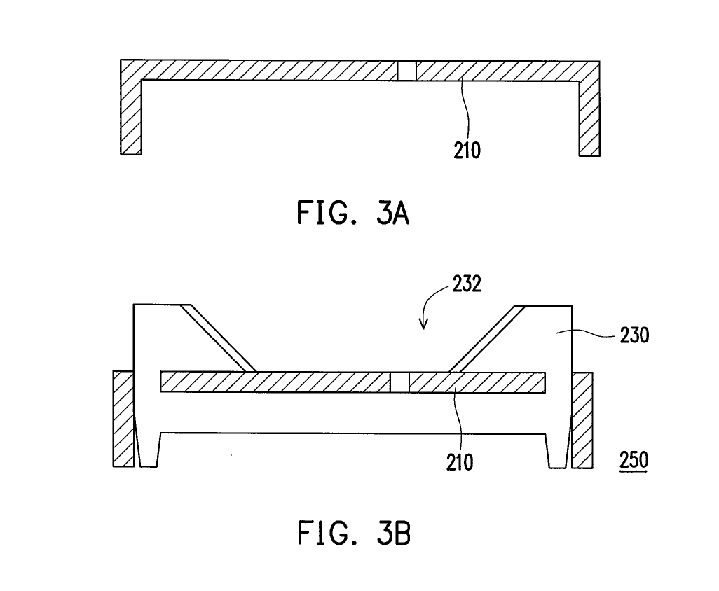

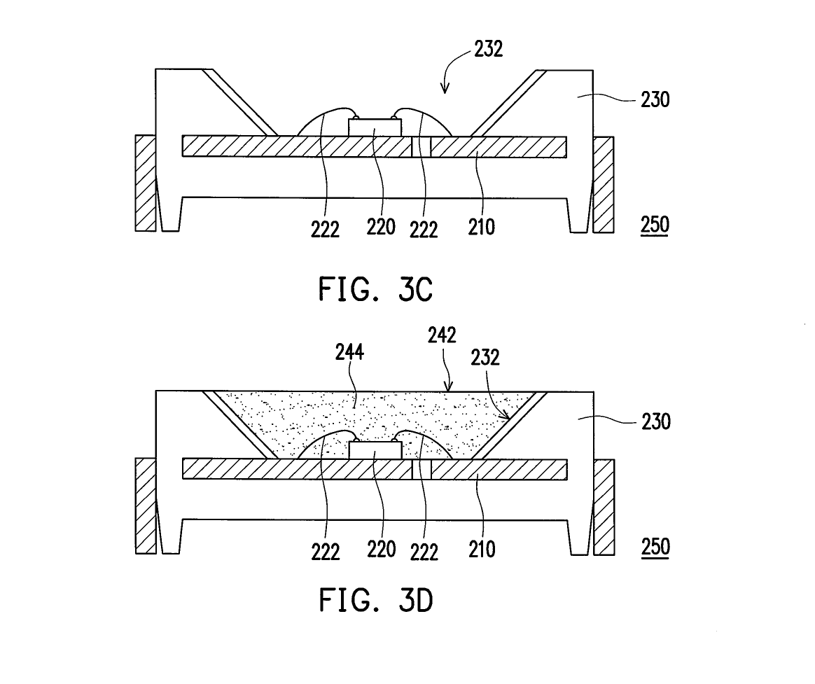

FIG. 2A to FIG. 2F show the schematic views of the fabrication method of the side-view LED package according to an embodiment of the present invention and FIG. 3A to FIG. 3D show the cross-sectional views of the fabrication method of the side-view LED package along the dash line A-A′ respectively in FIG. 2A to FIG. 2D. Referring to both FIG. 2A and FIG. 3A, a chip carrier 210 is provided first. In the present embodiment, the chip carrier 210 is a lead frame. Specifically, the lead frame used in the present embodiment is a lead frame having two leads. In an alternative embodiment of the present invention, the chip carrier 210 is a circuit board, for example. Preferably, the circuit board is a metal core printed circuit board (MCPCB) with excellent heat dissipation characteristic.

Referring to FIG. 2B and FIG. 3B, an opaque housing 230 bonded with the chip carrier 210 is formed. The opaque housing 230 has a cavity 232 for accommodating the light-emitting diode chip. In the prevent embodiment, the opaque housing 230 is formed by performing an injection molding process, for example. Specifically, the material of the opaque housing comprises plastics, metal, or metal oxide.

Referring to FIG. 2C and FIG. 3C, a chip-bonding process is performed for electrically connecting at least one light-emitting diode chip 220 with the chip carrier 210. In the present embodiment, a wire bonding process is used such that the light-emitting diode chip 220 is electrically connected with the chip carrier 210 through a plurality of bonding wires 222 (e.g. gold wires). In another embodiment, the light-emitting diode chip 220 may be electrically connected with the chip carrier 210 via a flip-chip bonding process or other bonding process used in the related art. Specifically, when the flip-chip bonding process is used to electrically connecting the light-emitting diode chip 220 and the chip carrier 210, a plurality of conductive bumps (e.g. solder bumps or gold bumps) are formed over the light-emitting diode chip 220 or the chip carrier 210, such that the light-emitting diode chip 220 and the chip carrier 210 is electrically connected to each other through the conductive bumps. Additionally, the light-emitting diode chip 220 for illuminating different color light (e.g. red, green and blue light) can be simultaneously disposed in the cavity 232 and be electrically connected with the chip carrier 210 so as to provide white light.

Referring to FIG. 2D and FIG. 3D, a transparent encapsulant 240 is formed in the cavity 232. The transparent encapsulant 240 has a side-view light output surface 242 uncovered by the opaque housing 230 and light emitted from the light-emitting diode chip 220 is output via the side-view light output surface 242. In the present embodiment, the transparent encapsulant 240 is formed by providing a transparent compound having phosphor material 244 mixed therein and filling the transparent compound into the cavity 232. In detail, the Phosphor material 244 mixed in transparent compound is used to convert a portion of the light emitted from the light-emitting diode chip 220. For example, the light-emitting diode chip 220 is capable of emitting blue light and the Phosphor material 244 (e.g. Yttrium Aluminum Garnet) mixed in transparent compound is capable of converting blue light into yellow light, such that white light is obtained by mixing blue light and yellow light. In an alternative embodiment of the present invention, a transparent compound without phosphor material mixed therein is used for filling into the cavity 232 of the opaque housing 230. For example, the transparent compound is filled into the cavity 232 via dispensing process or mold injection. As shown in FIG. 2D, the thickness d1 of the opaque housing 230 is usually greater than 0.6 millimeter because the opaque housing 230 is formed by conventional mold injection process.

Referring to FIG. 2E, in order to reducing the overall thickness of the side-view LED package 250, a portion of the opaque housing 230 and a portion of the transparent encapsulant 240 is removed. The method of removing the portion of the opaque housing 230 and the portion of the transparent encapsulant 240 is, for example, cutting or grinding. Thus, a top surface 246 of the transparent encapsulant 240 is uncovered or exposed by the opaque housing 230 beside the side-view light output surface 242, as shown in FIG. 3D. Referring to FIG. 2D and FIG. 2E, the overall thickness d1 of the opaque housing 230 and the transparent encapsulant 240 is about 0.5 millimeter to 0.8 millimeter before the portion of the opaque housing 230 and the portion of the transparent encapsulant 240 is removed. As shown in FIG. 2E, the side-view LED package 250 has a reduced overall thickness d2 of the opaque housing 230 and the transparent encapsulant 240. Specifically, after the portion of the opaque housing 230 and the portion of the transparent encapsulant 240 are removed, the reduced overall thickness d2 of the opaque housing 230 and the transparent encapsulant 240 is about 0.35 millimeter to 0.45 millimeter.

Referring to FIG. 2F, an opaque protective layer 260 is then formed on the top surface 246 of the transparent encapsulant 240 and the opaque housing 230 such that the side-view LED package 270 of the present embodiment is completed. The method of forming the opaque protective layer 260 is, for example, coating, screen printing, or sputtering. Thus, the opaque protective layer 260 is a film-like layer. As shown in FIG. 2F, the side-view LED package 270 of the present embodiment includes the chip carrier 210, the light-emitting diode chip 220, the encapsulant 280 and the opaque protective layer 260. The light-emitting diode chip 220 electrically connected with the chip carrier 210. The encapsulant 280 comprises the opaque housing 230 and the transparent encapsulant 240. The opaque housing 230 is bonded with the chip carrier 210, wherein the opaque housing 230 has the cavity 232 for accommodating the light-emitting diode chip 220. The transparent encapsulant 240 is disposed in the cavity 232, wherein the transparent encapsulant 240 has a side-view light output surface 242 (shown in FIG. 3D) uncovered by the opaque housing 230, wherein the transparent encapsulant 240 has a top surface 246 beside the side-view light output surface 242 (shown in FIG. 3D) uncovered by the opaque housing 230. Light emitted from the light-emitting diode chip 220 is output via the side-view light output surface 242 (drawn in FIG. 3D). Additionally, the opaque protective layer 260 is disposed on the top surface 246 of the transparent encapsulant 240 and the opaque housing 230.

Particularly, the material of the opaque protective layer 260 comprises a polymer and a plurality of particles mixed in the polymer, wherein the polymer comprises Oligo-polymer, Silicon, Epoxy or Acrylic and the material of the particles comprises metal, Titanium Dioxide, Aluminum Oxide or Phosphor. The thickness d3 of the opaque protective layer 260 is about 0.01 millimeter to 0.15 millimeter. It is noticed that the opaque protective layer 260 is a thin film so the thickness d3 is much smaller than the difference between thickness d1 and thickness d2. Thus, the overall thickness d4 (i.e. d2+d3) of the side-view LED package 270 is significantly reduced as compared with the thickness d1 of the side-view LED package 250. Furthermore, the method of reducing the overall thickness of the side-view LED package 270 is simple and easy. In one word, the present embodiment provides a fabrication method of LED package with high yield rate. Certainly, in another embodiment, both the top and bottom sides beside the side-view light output surface 242 of the opaque housing 230 can further be removed and two opaque protective layers 260 are formed respectively on the top and bottom surface of the transparent encapsulant 240 and the opaque housing 230. Such that, the thickness d4 of the side-view LED package 270 can be much thinner.

The fabrication method of the present invention provides is compatible with current process and the opaque housing can be formed without modifying the mold used in mold injection process. Therefore, the fabrication method of a side-view LED package of the present invention is simple and easy and the yield rate of fabricating a thin side-view LED package of the present invention is high.

One or part or all of these and other features and advantages of the present invention will become readily apparent to those skilled in this art from the following description wherein there is shown and described a preferred embodiment of this invention, simply by way of illustration of one of the modes best suited to carry out the invention. As it will be realized, the invention is capable of different embodiments, and its several details are capable of modifications in various, obvious aspects all without departing from the invention. Accordingly, the drawings and descriptions will be regarded as illustrative in nature and not as restrictive.

What is claimed is:

1. A fabrication method of a side-view light-emitting diode package, comprising:
providing a chip carrier;
forming an opaque housing bonded with the chip carrier, wherein the opaque housing has a cavity;
performing a chip-bonding process for electrically connecting a light-emitting diode chip with the chip carrier and the light-emitting diode chip is located in the cavity;
forming a transparent encapsulant disposed in the cavity, wherein the transparent encapsulant has a side-view light output surface uncovered by the opaque housing and light emitted from the light-emitting diode chip is output via the side-view light output surface;
removing a portion of the opaque housing and a portion of the transparent encapsulant for reducing an overall thickness of the opaque housing such that a top surface of the transparent encapsulant is uncovered by the opaque housing beside the side-view light output surface; and
forming an opaque protective layer on the top surface of the transparent encapsulant and the opaque housing.

2. The fabrication method of a side-view light-emitting diode package according to claim 1, wherein the chip carrier comprises a lead frame or a circuit board.

3. The fabrication method of a side-view light-emitting diode package according to claim 1, wherein a method for forming the opaque housing comprises injection molding.

4. The fabrication method of a side-view light-emitting diode package according to claim 1, wherein the chip-bonding process comprises a wire-bonding process or a flip-chip bonding process.

5. The fabrication method of a side-view light-emitting diode package according to claim 1, wherein a method for forming the transparent encapsulant comprises dispensing or mold injection.

6. The fabrication method of a side-view light-emitting diode package according to claim 1, wherein a method for forming the transparent encapsulant comprises:
providing a transparent compound having Phosphor material mixed therein; and
filling the transparent compound into the cavity.

7. The fabrication method of a side-view light-emitting diode package according to claim 1, wherein the overall thickness of the opaque housing and the transparent encapsulant is about 0.4 millimeter to 0.8 millimeter before the portion of the opaque housing and the portion of the transparent encapsulant is removed.

8. The fabrication method of a side-view light-emitting diode package according to claim 1, wherein the overall thickness of the opaque housing and the transparent encapsulant is about 0.35 millimeter to 0.45 millimeter after the portion of the opaque housing and the portion of the transparent encapsulant is removed.

9. The fabrication method of a side-view light-emitting diode package according to claim 1, wherein a method of removing the portion of the opaque housing and the portion of the transparent encapsulant comprises cutting or grinding.

10. The fabrication method of a side-view light-emitting diode package according to claim 1, wherein a method of forming the opaque protective layer comprises coating, screen printing, or sputtering.

11. The fabrication method of a side-view light-emitting diode package according to claim 1, wherein a material of the opaque protective layer comprises a polymer and a plurality of particles mixed therein.

12. The fabrication method of a side-view light-emitting diode package according to claim 11, wherein the polymer comprises Oligo-polymer, Silicon, Epoxy or Acrylic.

13. The fabrication method of a side-view light-emitting diode package according to claim 11, wherein a material of the particles comprise metal, Titanium Dioxide, Aluminum Oxide or Phosphor.

14. The fabrication method of a side-view light-emitting diode package according to claim 1, wherein a thickness of the opaque protective layer is about 0.01 millimeter to 0.15 millimeter.

15. A side-view light-emitting diode package, comprising:
a chip carrier;
a light-emitting diode chip electrically connected with the chip carrier;
an encapsulant, comprising:
an opaque housing bonded with the chip carrier, wherein the opaque housing has a cavity for accommodating the light-emitting diode chip;
a transparent encapsulant disposed in the cavity, wherein the transparent encapsulant has a side-view light output surface uncovered by the opaque housing, the transparent encapsulant has a top surface beside the side-view light output surface uncovered by the opaque housing, and light emitted from the light-emitting diode chip is output via the side-view light output surface; and
an opaque protective layer disposed on the top surface of the transparent encapsulant and the opaque housing.

16. A side-view light-emitting diode package according to claim 15, wherein the chip carrier comprises a leadframe or a circuit board.

17. A side-view light-emitting diode package according to claim 15, wherein the overall thickness of the encapsulant and the opaque protective layer is about 0.35 millimeter to 0.45 millimeter.

18. A side-view light-emitting diode package according to claim 15, wherein a material of the opaque protective layer comprises a polymer and a plurality of particles mixed therein.

19. A side-view light-emitting diode package according to claim 18, wherein the polymer comprises Oligo-Polymer, Silicon, Epoxy or Acrylic.

20. A side-view light-emitting diode package according to claim 18, wherein a material of the particles comprise metal, Titanium Dioxide, Aluminum Oxide or Phosphor.

21. A side-view light-emitting diode package according to claim 15, wherein a thickness of the opaque protective layer is about 0.01 millimeter to 0.15 millimeter.

22. A side-view light-emitting diode package according to claim 15, wherein a material of the transparent encapsulant comprises Silicon, Epoxy or Acrylic.

23. A side-view light-emitting diode package according to claim 22, wherein a material of the transparent encapsulant further comprises a Phosphor material.
